(19) United States
(12) Patent Application Publication
(10) Pub. No.: US 2007/0107929 A1
(43) Pub. Date: May 17, 2007

(54) Insulator integrated with clamp

(75) Inventor: Chul-Woong Park, Ansan-city (KR)

Correspondence Address: SUGHRUE MION, PLLC, 2100 PENNSYLVANIA AVENUE, N.W., SUITE 800, WASHINGTON, DC, 20037, US

(73) Assignee: EDI International, Inc.

(21) Appl. No.: 10/565,235

(22) PCT Filed: Jul. 21, 2004
(86) PCT No.: PCT/KR04/01817

§ 371 Date: Nov. 16, 2006

(30) Foreign Application Priority Data
Jul. 21, 2003 (KR) 10-2003-0049628
Feb. 19, 2004 (KR) 10-2004-0010883
Mar. 22, 2004 (KR) 20-2004-0007830

(51) Int. Cl. H05K 7/14

(52) U.S. Cl. 174/138 D

(57) ABSTRACT

The present invention relates to an insulator integrated with a clamp. The insulator integrated with a clamp according to the present invention includes a center rod (10), a connecting cap (20), and a clamp (50). The center rod (10) includes an insulating rod (12) made of a glass material, and an insulating coating (14) made of a polymer material. The connecting cap (20) is connected to a first end of the center rod (10). The clamp (50) includes a body (52) provided with a wedge-shaped casing unit (521) having an inner space and a connecting unit (522) formed on one end of the casing unit, and a pair of jaw elements (54) disposed in the inner space of the casing unit and pushed inward by springs, so that an interval between the jaw elements is reduced to perform a clamping operation.

### TECHNICAL FIELD

The present invention relates, in general, to an insulator for supporting a power cable and, more particularly, to an insulator integrated with a clamp, which has an easily manufactured structure, and in which the insulator is integrated with the clamp for connection to a power cable.

### BACKGROUND ART

Generally, a power cable is installed in various forms, either above ground or underground, to deliver power from a power plant to an individual consumer. A method of utilizing electric poles has been generally used as a method of installing a power cable above ground.

According to the method of supporting a power cable using electric poles, the electric poles are installed at regular intervals, and the power cable is supported by the electric poles, thus stably maintaining the power cable in the correctly installed position.

The electric poles and the power cable are connected to each other through an insulation structure to prevent a current flowing from the power cable to the electric poles. This insulation structure is formed in such a way that an insulator is positioned between a power cable and a supporting member. The supporting member is mounted on each electric pole and supports the power cable.

That is, the supporting member and the power cable are connected to each other through the insulator, thus preventing the current flowing from the power cable to the electric poles.

In this case, insulators are classified into a ceramic insulator made of a ceramic material and a composite insulator made of a polymer material, such as glass, silicon or Ethylene Propylene Diene Monomer (EPDM). The ceramic insulator is advantageous in that it has better insulating properties, but disadvantageous in that there is a high risk of damage during transportation and installation; the ceramic insulator has a heavy weight, and; it is inconvenient to connect the ceramic insulator to a fitting.

The composite insulator is designed to overcome the disadvantages of the ceramic insulator, and is comprised of a center rod 10, and metal connecting caps 20 and 20′ situated at both ends of the center rod 10 to connect the center rod 10 to a power cable and a fitting, respectively, as shown in FIG. 1.

In this case, the center rod 10 includes an insulating rod 12 made of a glass material, and an insulating coating 14 made of a polymer material constituting a plurality of disc-type fins 141 covering the insulating rod 12, as shown in FIG. 1. The composite insulator is characterized in that, since it has a light weight according to the properties of materials of the insulating rod 12 and the insulating coating 14 that constitute the center rod 10, it can be easily carried and installed.

For one of the connection structures between the composite insulator and the power cable, a so-called clamp scheme is used in which the connecting cap 20 at one end of the center rod 10 is attached to a fitting 110 (refer to FIG. 2) and the connecting cap 20′ at the other end of the center rod 10 is attached to a power cable 100 through a clamp 30.

The clamp 30 (refer to FIG. 1) is comprised of various components, such as a body 32, a pair of jaw elements 34 mounted on the body 32, and springs (not shown) used for the mechanical operation of the jaw elements 34. The body 32 includes a trapezoid-shaped casing unit 321 having an opening formed therein to narrow toward the end thereof and a bar-shaped connecting unit 322 formed on one end of the casing unit 321 and connected to the center rod 10, through connection cap 20′.

In this case, the casing unit 321 has a shape with an opened top to allow a control lever 341 formed on one jaw element 34 to be projected upward from the casing unit 321, and the casing unit 321 is constructed so that the tops of both sidewalls thereof are oppositely bent inward to form cover units 323 so as to prevent the jaw elements 34 provided in the casing unit 321 from deviating from the casing unit 321.

Such a clamp 30 is operated in such a way that the jaw elements 34 are pushed inward by the springs after the jaw elements 34 are positioned in the inner space of the casing unit 321, so that the gap between the jaw elements 34 becomes small enough to perform a clamping operation. In this case, the connecting unit 322 is connected to one connecting cap 20′ by a cotter 40 and a pin 42, so that the clamp 30 is connected to the insulator.

Therefore, in the conventional composite insulator, the connecting cap 20 at one end of the center rod is connected to the fitting 110, and the connecting cap 20′ at the other end thereof is connected to the clamp 30, as shown in FIG. 2. Furthermore, the composite insulator supports the power cable 100 is supported in such a way by being clamped by the jaw elements 34 of the clamp 30.

In the meantime, with this conventional composite insulator setup, several problems may occur due to the connection structure between the clamp 30 and the center rod 10, and the structure of the clamp 3)0 which are described in detail.

First, in the connection structure between the clamp 30 and the center rod 10, a problem of low productivity and efficiency during installation is caused due to the reason that the structure between the connecting cap 20′ and the clamp 30 must be designed in a complicated form in which the cotter 40 penetrates through the connecting cap 20′ so as to accommodate a cotter-pin scheme. Additional parts, such as the cotter 40 and the pin 42, are required, and the operation of connecting the connecting cap 20′ and the clamp 30 to each other is required prior to the installation.

Furthermore, according to the cotter-pin scheme, a strong shear force is applied to both the cotter 40 and the connecting cap 20′, so that the cotter 40 or the connecting cap 20′ may be damaged or the pin 42 fastening the cotter 40 may fall out and then the clamp 30 may be separated from the center rod 10. When the clamp 30 is separated from the center rod 10, the power cable 100 may be separated from the electric pole 120, thus badly affecting the stability of the supply of power.

Furthermore, the problem of the structure of the clamp 30 itself is based on the manufacturing method thereof. That is, since the clamp 30 is formed and manufactured as a single structure by molding a core must be used to obtain a space within the casing unit 321 according to the characteristics of the molding in order to form the cover unit 323 having an inwards bending shape on the top of the casing unit 321.

The core is used to form an opening in a formed product by making molding sand in a specific shape and arranging this molding sand in a metal mold. Therefore, there occurs a problem in that the core formed using a chemical adhesive, so that environmental pollution is caused and disposal costs are incurred when the core is disposed of and the costs required to manufacture products related to the core are increased.

Furthermore, when the core is used the inner surface of the casing unit 321 is roughly formed according to the properties of a core made of molding sand so that several operational problems may occur, including a condition in which the motions of both jaw elements 34 coming into contact with the inner surface of the casing unit 321 are not smooth.

### DISCLOSURE OF INVENTION

Accordingly, the present invention has been made keeping in mind the above problems occurring in the prior art, and an object of the present invention is to provide an insulator integrated with a clamp and a connecting cap, so that the stability of supporting a power cable and operational efficiencies during installation is improved and which employs a structure of manufacturing the clamp without using a core, so that manufacturing productivity is improved.

In order to accomplish the above objective, the present invention provides an insulator integrated with a clamp, comprising a center rod comprised of an insulating rod made of a glass material, and an insulating coating made of a polymer material to cover the insulating rod; a connecting cap connected to one end of the center rod; and the clamp comprised of a body provided with a wedge-shaped casing unit having an inner space formed to narrow toward an end of the casing unit and a connecting unit formed on the other end of the casing unit, and a pair of jaw elements positioned in the inner space of the casing unit and pushed inward by springs, so that an interval between the jaw elements is reduced to perform a clamping operation, and the connecting unit having a permanent connection to the other end of the center rod.

Preferably, the connecting unit of the clamp may be formed in a pipe shape with a diameter slightly greater than a diameter of the insulating rod so that the appropriate end of the insulating rod is tightly fitted into the connecting unit, thus enabling the clamp and the center rod to be fixedly connected to each other.

Preferably, the casing unit of the clamp may be formed to have a fully opened top; and the clamp may further comprise separate cover panels attached to tops of both sidewalls of the casing unit so that the cover panels partially

cover the opened top and thus prevent the jaw elements included in the casing unit from deviating upwards from the casing unit.

### DESCRIPTION OF DRAWINGS

The above mentioned, as well as other objects, features and advantages of the present invention will be more clearly understood from the following detailed description taken in conjunction with the accompanying drawings, in which:

FIG. 1 is a perspective view showing the structure of a conventional composite insulator/clamp combination;

FIG. 2 is a view showing an example of the supporting of a power cable using the conventional composite insulator/clamp combination;

FIG. 3 is an exploded perspective view showing the structure of an insulator integrated with a clamp according to an embodiment of the present invention;

FIG. 4 is a perspective view showing the structure of the assembled insulator integrated with a clamp according to the embodiment of the present invention;

FIG. 5 is a perspective view showing the structure of the clamp according to the embodiment of the present invention;

FIG. 6 is a perspective view showing the operation of the clamp according to the embodiment of the present invention; and

FIG. 7 is a view showing an example of the supporting of a power cable using the insulator integrated with a clamp according to the embodiment of the present invention.

### BEST MODE

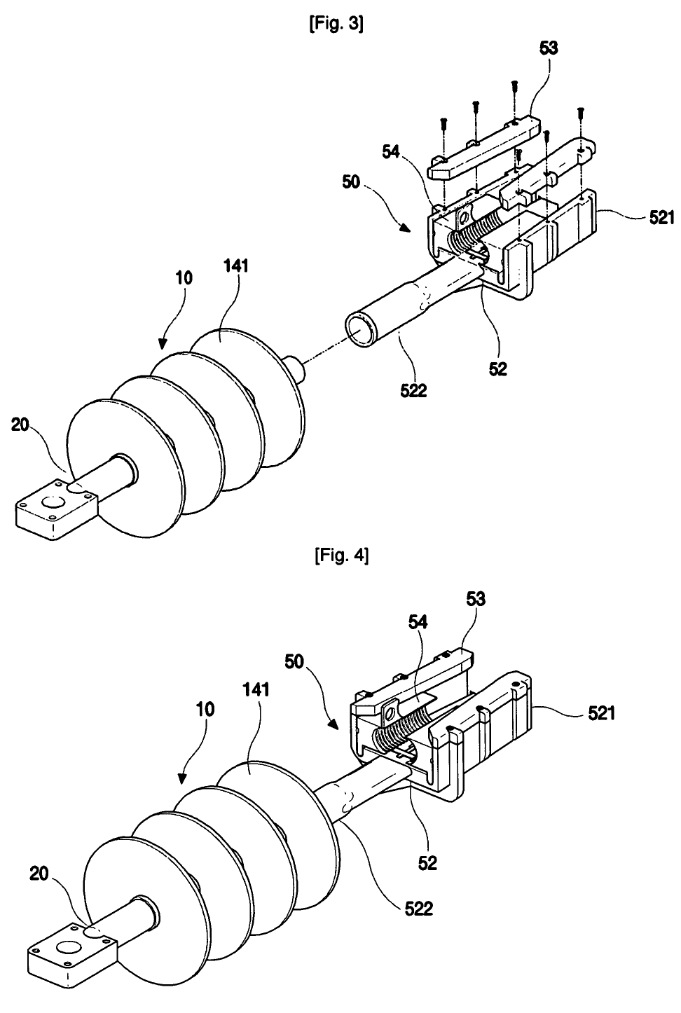

Hereinafter, embodiments of the present invention will be described in detail with reference to FIGS. 3 through 7.

Reference should now be made to the drawings, in which the same reference numerals are used throughout the different drawings to designate the same or similar components.

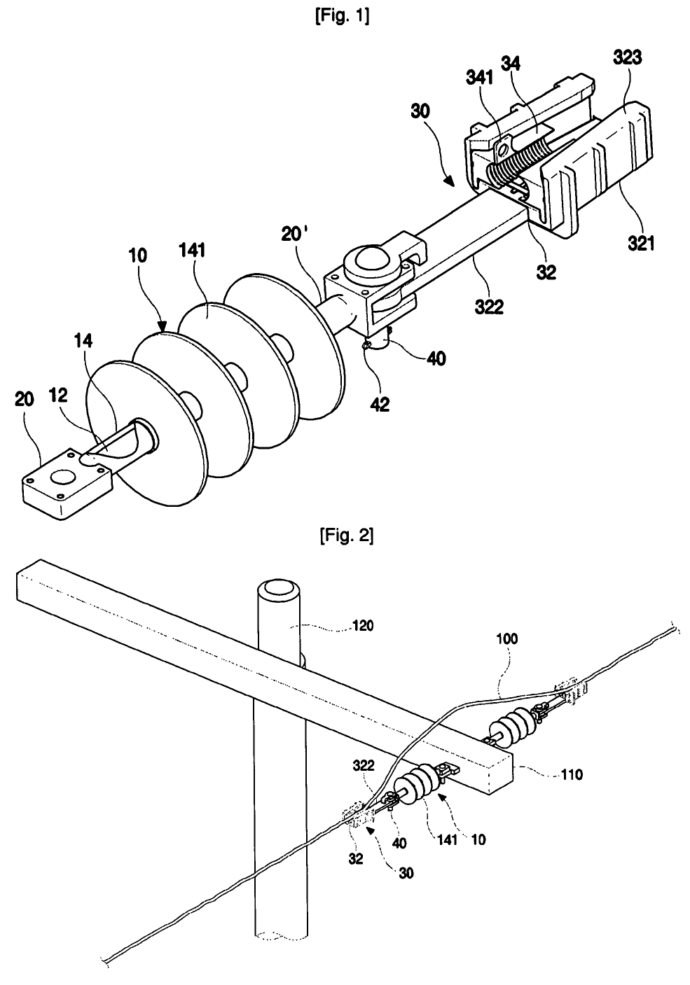

An insulator integrated with a clamp according to the embodiment of the present invention includes a clamp 50 attached to one end of the center rod 10, and a connecting cap 20 attached to the other end of the center rod 10, as shown in FIGS. 3 and 4. The center rod 10 is comprised of an insulating rod 12 (refer to FIG. 1) made of a glass material and an insulating coating 14 made of a polymer material to cover the insulating rod 12, similar to the conventional composite insulator.

The clamp 50 includes various components, such as a body 52, a pair of jaw elements 54 mounted on the body 52, springs (not shown) required for the mechanical operation of the jaw elements 54. The body 52 includes a trapezoid-shaped casing unit 521 having an opening formed therein to narrow toward the end thereof and a bar-shaped connecting unit 522 formed on one end of the casing unit 521 and tightly connected to the center rod 10.

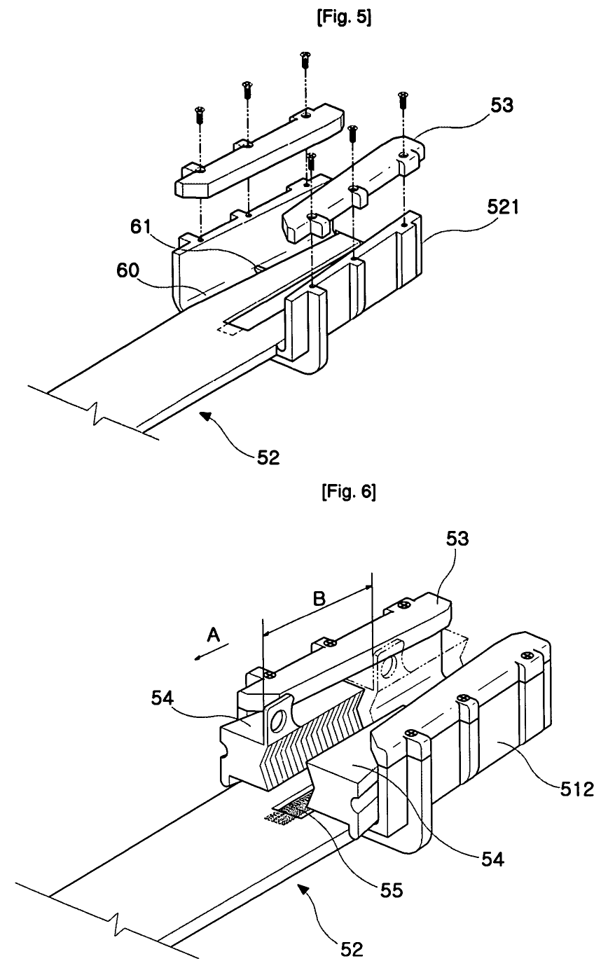

Furthermore, as shown in FIGS. 5 and 6, the two guide channels 60 are formed in the bottom of casing unit 521 to provide a sliding route for the jaw elements 54. The important aspect of the guide channels 60 is that a limitation stub 61 is formed in one or both of the guide channels to limit the jaw elements' movement. As a counterpart of the limitation stub 61, a detach prevention stub (not shown) is formed in the bottom of the one or both of the jaw elements.

Specifically, when the jaw elements are moved in direction A (refer to FIG. 6), after moving for predetermined distance B, the jaw elements are stopped by the limitation stub 61. Without the limitation stub 61, there is very high possibility for jaw elements 54 to be detached from casing unit 521, when jaw elements are moved in direction A to widen the space between each jaw elements.

The connecting unit 522 is formed in a pipe shape having a diameter slightly greater than that of the insulating rod. One end of the insulating rod 12 is tightly fitted into the connecting unit 522, so that the clamp 50 and the center rod 10 can be permanently connected to each other.

Furthermore, according to the embodiment of the present invention, the casing unit 521 of the clamp 50 is formed to have a fully opened top, and separate cover panels 53 are attached to the tops of both sidewalls of the casing unit 521, instead of conventional cover units 323 integrated with the casing unit 321 (refer to FIG. 1).

The cover panels 53 are formed to have a width exceeding the thickness of each sidewall of the casing unit 521, and fastened to the tops of the casing unit 521 through fastening bolts, after the jaw elements 54 are inserted in the casing unit 521, thus preventing the jaw elements 54 from deviating from the casing unit 521.

In the above-described insulator integrated with a clamp according to the embodiment of the present invention, the clamp 50 and the center rod 10 are fixedly connected to each other, so that there is no need to execute a separate process of engaging the clamp 30 (refer to FIG. 1) with the center rod 10 in a cotter-pin manner prior to the connection to the power cable 100, as in the case of a conventional insulator.

Furthermore, with regard to the shape of the clamp 50, since the clamp 50 is constructed without a conventional complicated structure for the cotter-pin connection, but rather with a simple pipe-shaped connecting unit 522 into which the insulating rod 12 is tightly fitted, thus improving structural strength at the connection points.

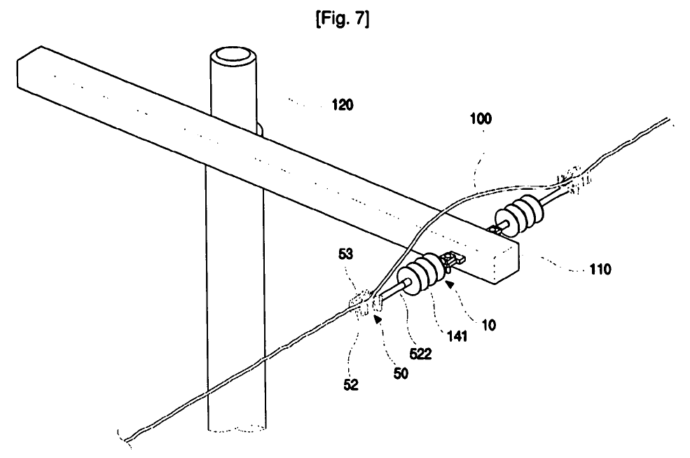

In the insulator integrated with a clamp according to the embodiment of the present invention having the above construction, the connecting cap 20 at one end of the center rod 10 is attached to the fitting 110 and then mounted on the electric pole 120, as shown in FIG. 5. The power cable 100 is supported in such a way that it is clamped by the jaw elements 54 of the clamp 50(FIG. 7).

According to the embodiment of the present invention, the body of the clamp can be formed without using a core to form an opening in the casing unit 521, as the structure of the casing unit 521 has a fully opened top.

Therefore, since the inner surface of the casing unit 521 is formed smoothly, the operation of the jaw elements 54 is improved thus solving various problems occurring due to the use of the core.

### INDUSTRIAL APPLICABILITY

As described above, the present invention provides an insulator integrated with a clamp, which is implemented with a simple structure in which a center rod and a clamp are permanently connected to each other, so that the low productivity and efficiency during installation is improved and in which the connection part between the clamp and the center rod is strongly constructed so that the stability of supporting a power cable is improved thus stably supplying power.

Furthermore, the present invention is advantageous in that, since it does not require a core in a process of manufacturing the body of a clamp, problems related to the increased costs and environmental pollution attributable to the use of the core do not occur.

Although the preferred embodiment of the present invention has been disclosed for illustrative purposes, those skilled in the art will appreciate that various modifications, additions and substitutions are possible, without departing from the scope and spirit of the invention as disclosed in the accompanying claims.

1. An insulator integrated with a clamp, comprising:
a center rod comprised of an insulating rod made of a glass material, and an insulating coating made of a polymer material to cover the insulating rod;
a connecting cap connected to a first end of the center rod; and
the clamp comprised of a body provided with a wedge-shaped casing unit having an inner space formed to narrow toward an end of the casing unit and a connecting unit formed on one end of the casing unit, and a pair of jaw elements positioned in the inner space of the casing unit and pushed inward by springs, so that the gap between the jaw elements is reduced to perform a clamping operation, and with the connecting unit being permanently connected to an end of the center rod.

2. The insulator integrated with a clamp according to claim 1, wherein the connecting unit of the clamp is formed in a pipe shape with a diameter slightly greater than a diameter of the insulating rod, so that one end of the insulating rod is tightly fitted into the connecting unit, thus enabling the clamp and the center rod to be permanently connected to each other.

3. The insulator integrated with a clamp according to claim 1, wherein:
the casing unit of the clamp is formed to have a fully opened top; and
the clamp further comprises separate cover panels attached to the tops of both sidewalls of the casing unit so that the cover panels partially cover the opened top and then prevent the jaw elements included in the casing unit from deviating upward from the casing unit.

4. The insulator integrated with a clamp according to claim 1, wherein the clamp further comprising the two guide channels are formed in the bottom of the casing unit to provide the sliding routes for the jaw elements, and a limitation stub formed in at least one of said guide channels to limit the jaw elements' movement.
